(19) United States
(12) Patent Application Publication
(10) Pub. No.: US 2023/0255111 A1
(43) Pub. Date: Aug. 10, 2023

(54) ORGANIC LIGHT-EMITTING DIODE

(71) Applicant: FLASK CORPORATION, Yonezawa-shi, Yamagata (JP)

(72) Inventors: Hisayuki KAWAMURA, Yonezawa-shi, Yamagata (JP); Masahiro IGARASHI, Yonezawa-shi, Yamagata (JP)

(21) Appl. No.: 18/015,197

(22) PCT Filed: Aug. 19, 2020
(86) PCT No.: PCT/JP2020/031196

§ 371 Date: Jan. 9, 2023

(51) Int. Cl. H10K 85/60; H10K 85/30

(52) U.S. Cl. CPC H10K 85/6574; H10K 85/615; H10K 85/633; H10K 85/636; H10K 85/654; H10K 85/626; H10K 85/6572; H10K 85/30; H10K 50/15

(57) ABSTRACT

An organic light-emitting diode that can work at lower voltage and higher efficiency is provided by a suitable combination of a hole transport layer and electron barrier layer. In the organic light-emitting diode, an organic film including at least a light-emitting layer is sandwiched between an anode and cathode, satisfying (i) to (iv). (i) The organic film includes a hole transport layer containing a triamine derivative represented by general formula (1). (ii) The hole transport layer has a thickness of 40 to 400 nm. (iii) A part or the whole of the hole transport layer contains 0.1 to 20 wt % of an acceptor compound, and/or the hole transport layer includes a hole injection layer made of the acceptor compound between the anode and hole transport layer. (iv) An electron barrier layer containing a monoamine derivative represented by general formula (2) is included between the hole transport layer and light-emitting layer.

### TECHNICAL FIELD

The present invention relates to an organic light-emitting diode having a triamine derivative and a monoamine derivative in a hole transporting zone.

### BACKGROUND ART

When a voltage is applied to a pair of electrodes constituting an organic light-emitting diode, holes from an anode and electrons from a cathode are injected into a light-emitting layer including organic compounds as luminescence materials, and the injected electrons and holes are recombined to form exciton in the luminous organic compounds. Consequently, the excited organic compounds emit luminescence. Because of being a self-luminous device, the organic light-emitting diode is superior in brightness and visibility to the liquid crystal device, and gives us a clear projected image. The organic light-emitting diode is expected as a light-emitting device which has high luminous efficiency, high resolution, low electricity consumption, long lifetime and thin profile design, while making use of the advantage of the self-luminous device.

The organic light-emitting diode tends to induce a short circuit current between electrodes, because the organic compound layers sandwiched between the pair of electrodes have a thickness of no more than 1 μm or less. To avoid this short circuit current, usually the device configuration is adopted to maximize the thickness of the hole transport layer of the organic compound layers. It is reasonable to thicken the hole transport layer which has the highest mobility to suppress the voltage rise caused by thickening the layers as much as possible.

Amines are known as materials used for the hole transport layer. Amines are easily positively charged and easily serve as a carrier in the hole transport layer because of attracting hydrogen atoms, so that various amine derivatives are being put to the test. For example, it is disclosed in PTL 1 that the organic light-emitting diode has a two-layer organic structure of an organic hole transport layer and an organic light-emitting layer and a three-layer organic structure of the organic hole transport layer, the organic light-emitting layer and the electron transport layer between a hole injection electrode (anode) and an electron injection electrode (cathode), and that both the organic hole transport layers contain an aromatic triamine derivative or a triamine derivative having aromatic moieties.

Another attempt to improve the performance of the organic light-emitting diode is to place an electron barrier layer besides the hole transport layer in the hole transporting zone. The placement of the electron barrier layer between the light-emitting layer and the hole transport layer confines electrons in the light-emitting layer and enhances a probability of recombining charge in the light-emitting layer, which leads to improving high luminous efficiency and emission lifetime.

PTL 2 gives an example of the improved luminous characteristics of the light-emitting diode thanks to placing the electron barrier layer. That is, the example of an electron barrier layer made of a monoamine derivative, more specifically, a monoamine derivative having an aromatic monoamine derivative or a monoamine derivative having aromatic moieties is disclosed.

In order to improve the charge injection in the hole transport layer, the addition of a small amount of acceptor compound thereto is also well known. PTL 3 gives an example of vapor depositing a radialene derivative as p-type semiconductor dopant or as a hole injection material.

### CITATION LIST

### Patent Literature

PTL 1: Japanese Patent No. 3565870
PTL 2: Japanese Unexamined Patent Application Publication No. 2016-092297
PTL 3: Japanese Translation of PCT International Application Publication No. 2018-506137

### SUMMARY OF INVENTION

### Technical Problem

An object of the present invention is to provide an organic light-emitting diode that can work at lower voltage and higher efficiency in a suitable combination of a hole transport layer with an electron barrier layer.

### Solution to Problem

In the organic light-emitting diode of the present invention, an organic thin film having at least a light-emitting layer is sandwiched between an anode and a cathode. The organic thin film satisfies the following (i) to (iv).

(i) The organic thin film includes a hole transport layer containing a triamine derivative represented by the following general formula (1).

(ii) The hole transport layer has a thickness of 40 to 400 nm.

(iii) A part or the whole of the hole transport layer contains 0.1 to 20% of an acceptor compound, and/or the hole transport layer includes a hole injection layer made of the acceptor compound between the anode and the hole transport layer.

(iv) An electron barrier layer containing a monoamine derivative represented by the following general formula (2) is included between the hole transport layer and the light-emitting layer.

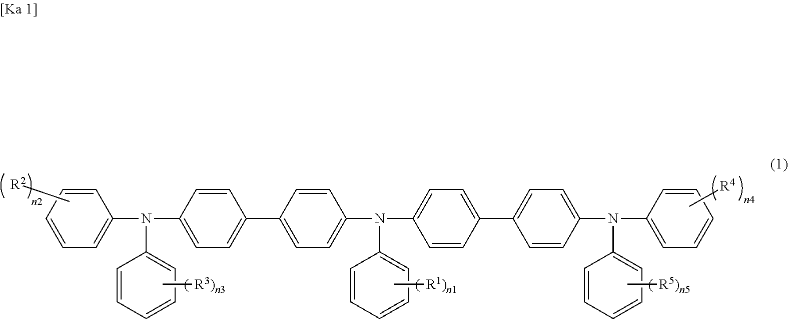

In the general formula (1), R¹ to R⁵ are each independently hydrogen, deuterium, fluorine, a silyl group, an alkyl group having 1 to 6 carbon atoms, an aryl group having 6 to 30 core carbon atoms or a heteroaryl group having 5 to 30 core atoms; n1 to n5 are integers of 1 to 5 and when n1 to n5 are 2 or more, R¹ to R⁵ may each be the same or different; among R¹ to R⁵, two adjacent substituents may connect each other to form a saturated or unsaturated ring.

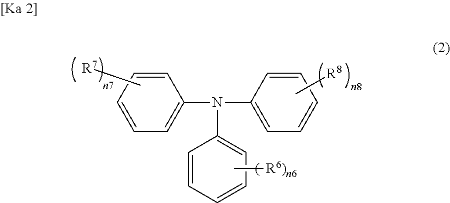

In the general formula (2), R⁶ to R⁸ are each independently hydrogen, deuterium, fluorine, a silyl group, an alkyl group having 1 to 6 carbon atoms, an aryl group having 6 to 30 core carbon atoms or a heteroaryl group having 5 to 30 core atoms; n6 to n8 are integers of 1 to 5 and when n6 to n8 is 2 or more, R⁶ to R⁸ may each be the same or different; and two adjacent substituents may connect each other to form a saturated or unsaturated ring.

The acceptor compound has a reversible oxidation-reduction potential in a range of +0.10 to +0.50 V preferably by cyclic voltammetry in acetonitrile solution on the basis of the ferrocenium/ferrocene redox couple (Fc+/Fc).

Preferably, the acceptor compound is a radialene derivative represented by the following general formula (3).

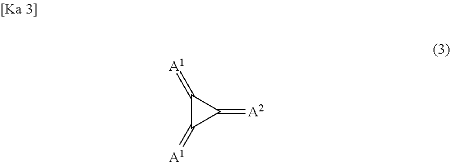

In the general formula (3), A¹ and A² are each independently cyanomethylidene group modified by replacing hydrogen with an aryl group or a heteroaryl group;

the aryl group and the heteroaryl group are
4-cyano-2,3,5,6-tetrafluorophenyl,
2,3,5,6-tetrafluoropyridin-4-yl,
4-trifluoromethyl-2,3,5,6-tetrafluorophenyl,
2,4-bis(trifluoromethyl)-3,5,6-trifluorophenyl,
2,5-bis(trifluoromethyl)-3,4,6-trifluorophenyl,
2,4,6-tris(trifluoromethyl)-1,3-diazin-5-yl,
3,4-dicyano-2,5,6-trifluorophenyl,
2-cyano-3,5,6-trifluoropyridin-4-yl,
2-trifluoromethyl-3,5,6-trifluoropyridin-4-yl,
2,5,6-trifluoro-1,3-diazin-4-yl,
pentafluorophenyl or
3-trifluoromethyl-4-cyano-2,5,6-trifluorophenyl,
and at least one of the aryl and the heteroaryl is
2,3,5,6-tetrafluoropyridin-4-yl,
2,4-bis(trifluoromethyl)-3,5,6-trifluorophenyl,
2,5-bis(trifluoromethyl)-3,4,6-trifluorophenyl,
2,4,6-tris(trifluoromethyl)-1,3-diazin-5-yl,
3,4-dicyano-2,5,6-trifluorophenyl,
2-cyano-3,5,6-trifluoropyridin-4-yl,
2-trifluoromethyl-3,5,6-trifluoropyridin-4-yl,
2,5,6-trifluoro-1,3-diazin-4-yl or
3-trifluoromethyl-4-cyano-2,5,6-trifluorophenyl,
and A¹ and A² cannot be 2,3,5,6-tetrafluoropyridin-4-yl at the same time.

### Advantageous Effects of Invention

The present invention provides an organic light-emitting diode which can inject the current at lower voltage and higher efficiency compared with the existing device configuration and contribute to low electricity consumption.

### BRIEF DESCRIPTION OF DRAWINGS

FIG. 1 represents the structure of the organic light-emitting diode of the present invention.

### DESCRIPTION OF EMBODIMENTS

Hereinafter, suitable embodiments of the present invention will be described in detail making reference to the accompanying drawings.

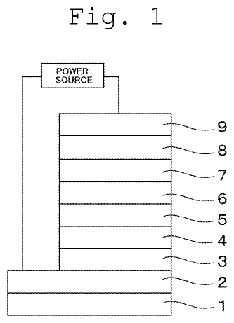

The organic light-emitting diode of the present invention has a structure in which an organic thin film including at least a light-emitting layer 5 is sandwiched between an anode 1 and a cathode 9. FIG. 1 represents a typical structure of an organic light-emitting diode having the organic thin film composed of a hole injection layer 2, a hole transport layer 3, an electron barrier layer 4, a hole barrier layer 6, an electron transport layer 7 and an electron injection layer 8 between the anode 1 and the cathode 9.

The feature of the present invention lies in the (i) to (iv) met by the hole injection layer 2, the hole transport layer 3 and the electron barrier layer 4 which constitute the organic thin film.

(i) The organic thin film includes a hole transport layer 3 containing a triamine derivative represented by the following general formula (1).

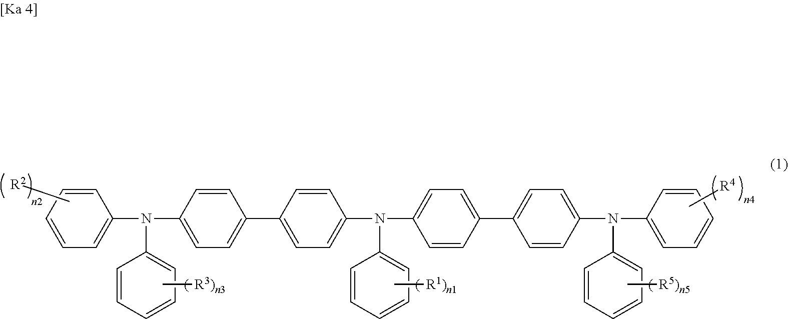

In the general formula (1), R¹ to R⁵ are each independently hydrogen, deuterium, fluorine, a silyl group, an alkyl group having 1 to 6 carbon atoms, an aryl group having 6 to 30 core carbon atoms or a heteroaryl group having 5 to 30 core atoms; n1 to n5 are integers of 1 to 5 and when n1 to n5 are 2 or more, R¹ to R⁵ may each be the same or different; among R¹ to R⁵, two adjacent substituents may connect each other to form a saturated or an unsaturated ring.

The silyl group is an alkylsilyl group or an arylsilyl group. The alkylsilyl group includes trimethylsilyl group, triethylsilyl group, tributylsilyl group, trioctylsilyl group, triisobutylsilyl group, dimethylethylsilyl group, dimethylisopropylsilyl group, dimethylpropylsilyl group, dimethylbutylsilyl group, dimethyl(t-butyl)silyl group, diethylisopropylsilyl group, vinyldimethylsilyl group, propyldimethylsilyl group and triisopropylsilyl group. The alkylsilyl group includes phenylsilyl group, diphenylsilyl group, triphenylsilyl group, 1-naphthylsilyl group, 2-naphthylsilyl group, and an alkylphenylsilyl group having 1 to 12 carbon atoms.

The alkyl group having 1 to 6 carbon atoms is a linear or a branched alkyl group. Specifically, methyl group, ethyl group, propyl group, isopropyl group, butyl group, isobutyl group, s-butyl group, t-butyl group, pentyl group, neopentyl group, isopentyl group, s-pentyl group, 3-pentyl group, t-pentyl group, hexyl group, 2-methylpentyl group, 3-methylpentyl group, 2,2-dimethylbutyl group, 2,3-dimethylbutyl group, etc. are included.

The aryl group having 6 to 30 core carbon atoms is a monocyclic or a fused polycyclic aromatic hydrocarbyl group which may have a substituent. Specifically, phenyl group, deuterated phenyl group, 1-naphthyl group, biphenyl group, p-methoxyphenyl group, p-t-butylphenyl group, tolyl group, m-tolyl group, o-tolyl group, xylenyl group, pentafluorophenyl group, phenanthryl group, pyrenyl group, fluorenyl group, 9,9′-bifluoren-2-yl group and fluoranthenyl group, etc. are included. As far as the effects of the present invention are not impaired, the aryl group may still include silicon, nitrogen and other atoms, such as 4-triphenylsilylphenyl group, 4-(diphenylamino)phenyl group and 4-(1-naphthylphenylamino) phenyl group.

The heteroaryl group having 5 to 30 core atoms may include either a monocyclic or a polycyclic heteroaryl group, for example, thienyl group, pyrrolyl group, pyridyl group, pyrrolidyl group, piperidyl group, imidazolyl group, pyrazolyl group, pyrazyl group, pyrimidyl group, pyridazyl group, piperazyl group, triazinyl group, 2,4-diphenyltriazinyl group, oxazolyl group, isooxazolyl group, morpholyl group, thiazolyl group, isothiazolyl group, furanyl group, indolyl group, carbazolyl group, 9-phenylcarbazolyl group, 4-(9H-carbazol-9-yl)phenyl group, quinolyl group, isoquinolyl group, benzimidazolyl group, quinazolyl group, quinoxalinyl group, phthalazyl group, purinyl group, pteridyl group, benzofuranyl group, dibenzofuranyl group, 4-(dibenzofuran-4-yl)phenyl group, coumaryl group, benzothiophenyl group, dibenzothiophenyl group, benzoxazolyl group, and benzthioxazolyl group.

Among R¹ to R⁵, two adjacent substituents may connect each other to form moieties, such as naphthalene, anthracene, phenanthrene, fluorene, 9,9-dimethylfluorene, 9,9-diphethylfluorene, dibenzofuran, carbazole, N-methylcarbazole, and N-phenylcarbazole.

Preferably, the triamine derivative represented by the general formula (1) are compounds of the following structural formulae.

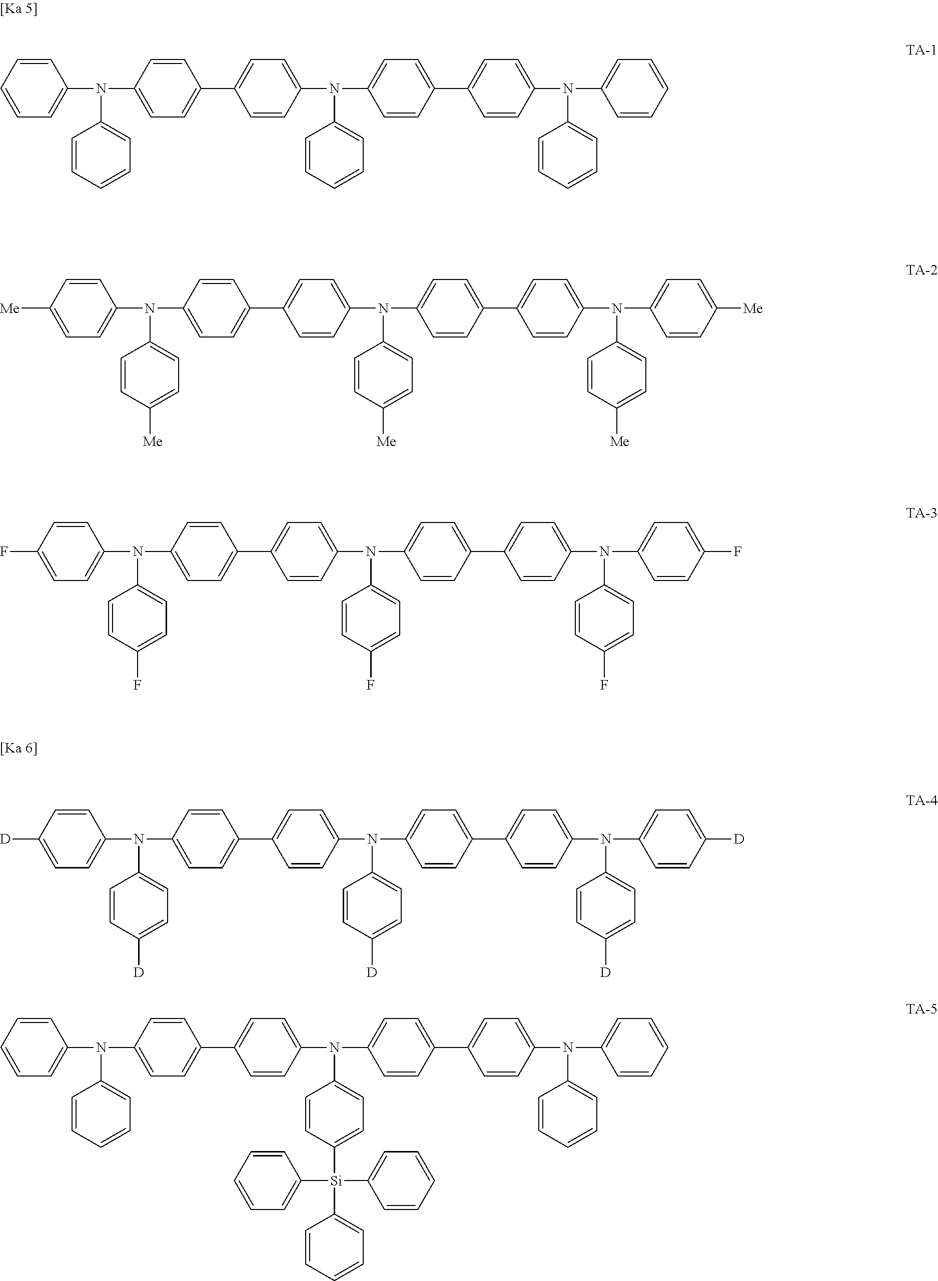

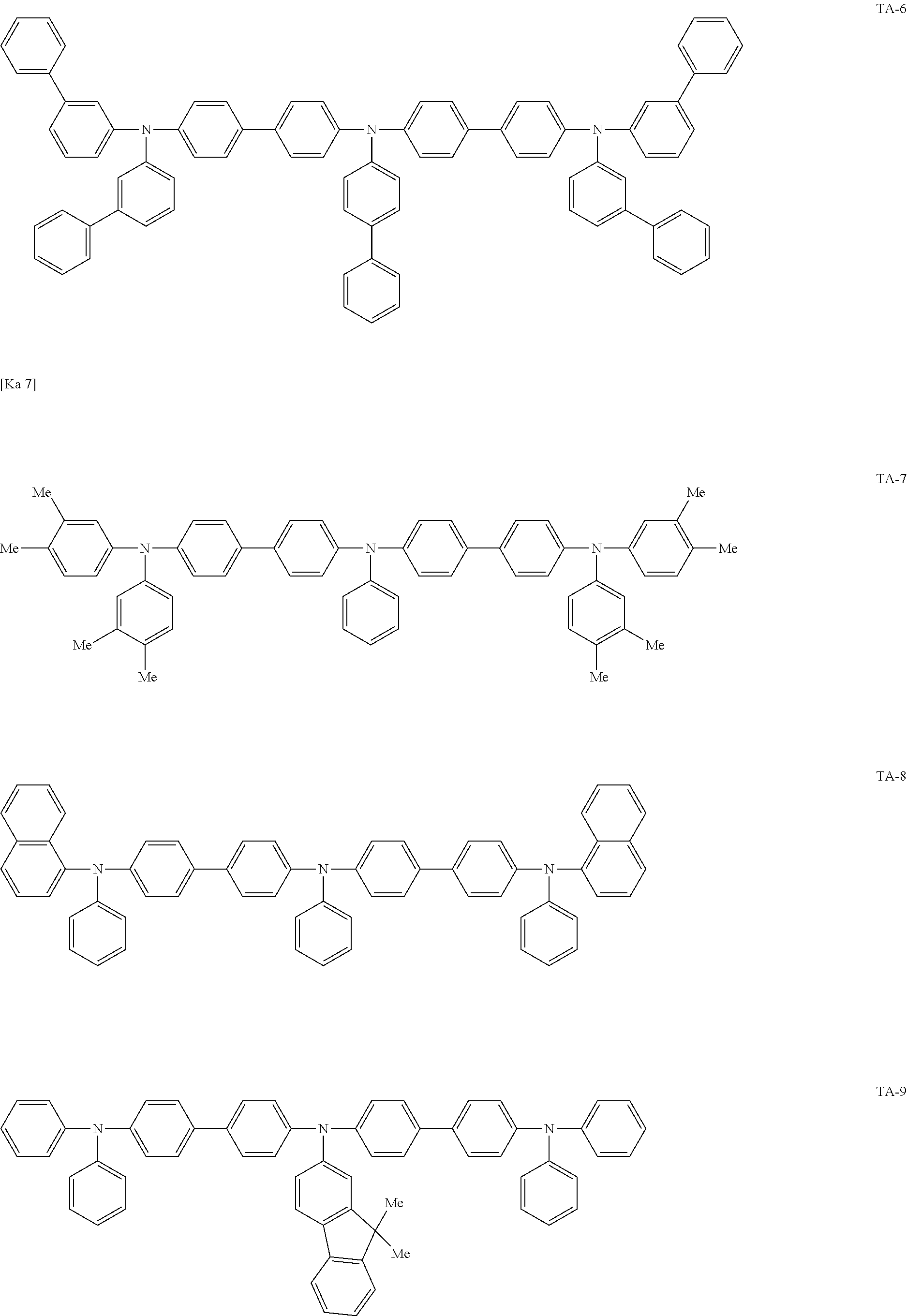

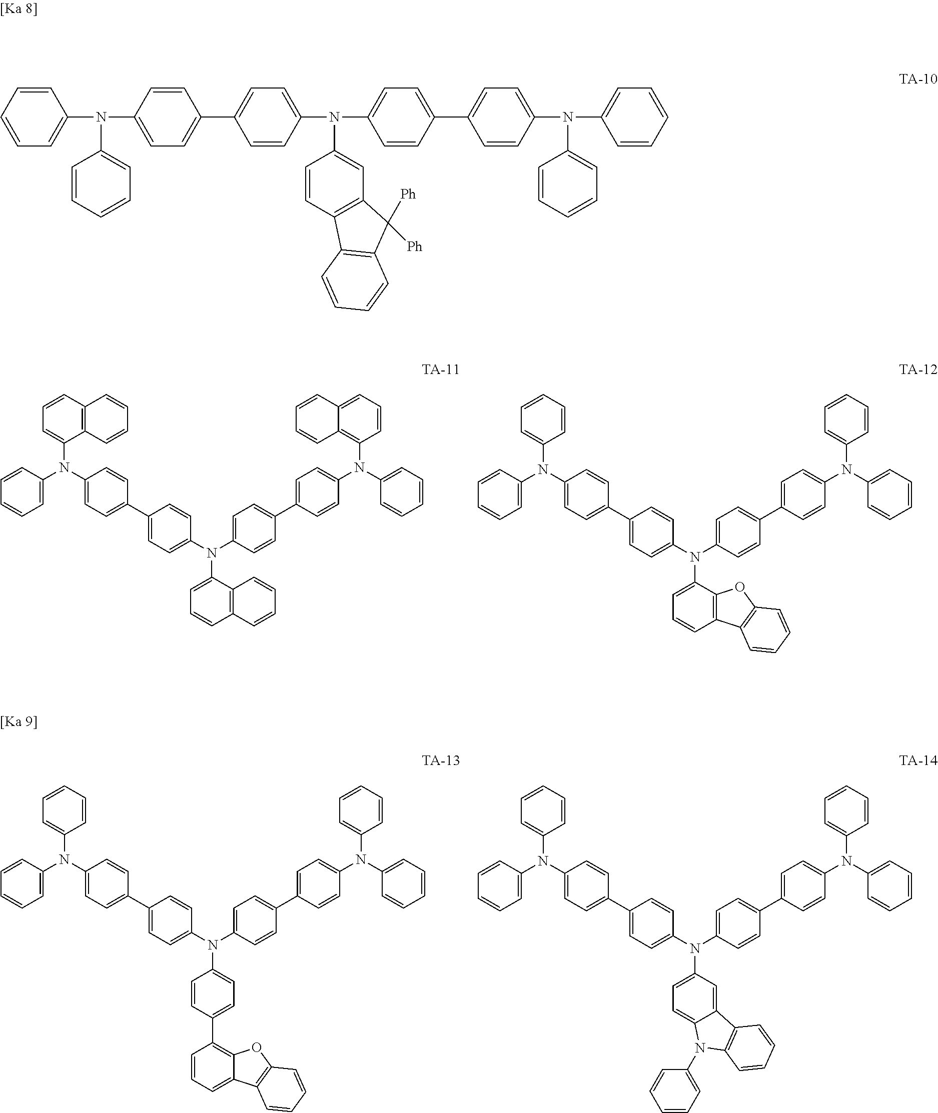

(ii) The hole transport layer 3 has a thickness of 40 to 400 nm, and preferably 60 to 200 nm. Having a thickness of less than 40 nm may cause defects such as pinholes on part of the hole transport layer 3, while having a thickness of more than 400 nm may cause the unevenness of thickness in the hole transport layer 3. Such defects cause the occurrence of current leakage.

(iii) A part or the whole of the hole transport layer 3 contains 0.1 to 20 wt % of the acceptor compound, and/or the hole transport layer includes a hole injection layer made of the acceptor compound between the anode 1 and the hole transport layer 3.

The acceptor compound may be contained in whole or in part of the hole transport layer 3. The content of the acceptor compound is 0.1 to 20 wt % on the total of the triamine derivative represented by the general formula (1) and the acceptor compound. The hole transport layer 3 having such composition may be formed by adding the acceptor compound to the triamine derivative and then coating the mixture, or may be formed by vapor deposition. In the case of the vapor deposition, the hole transport layer 3 is formed by heating the triamine derivative and the acceptor compound individually, and then forming the hole transport layer 3 in control of vapor deposition rate so that the composition ratio of the triamine derivative and the acceptor compound could be a ratio of 1:0.1 to 20.

Concerning the hole transport layer 3, the triamine derivative represented by the formula (1) may not be mingled with the acceptor compound, but a hole injection layer made of the acceptor compound may be placed between the anode 1 and the hole transport layer 3 instead. The hole injection layer made of the acceptor compound is formed by coating or vapor deposition. On a hole injection/transport layer where the triamine derivative represented by the formula (1) and the acceptor compound coexist, the hole transport layer 3 made of the triamine derivative represented by the formula (1) may be placed.

Both of the hole injection layer 2 made of the acceptor compound and a part or all of the hole transport layer 3 in which the acceptor compound is mingled may be placed. In this case, the acceptor compound is added so as to be 0.1 to 20 wt % relative to the total of the triamine derivative and the acceptor compound. Adding the acceptor compound to the hole transport layer 3 or the hole injection layer 2 accelerates electrons to flow into the electrode.

The acceptor compound preferably has a reversible oxidation-reduction potential in a range of +0.10 to +0.50 V obtained by cyclic voltammetry (CV) in acetonitrile solution on the basis of the ferrocenium/ferrocene redox couple (Fc+/Fc). Having the reversible oxidation-reduction potential, the acceptor compound transfers electrons faster than they are diffused during the electrode reaction, which proves the acceptor compound to be useful as dopant. The cyclic voltammogram shows that the acceptor compound serves as P type dopant.

Preferably, the acceptor compound is compounds of the following structural formulae.

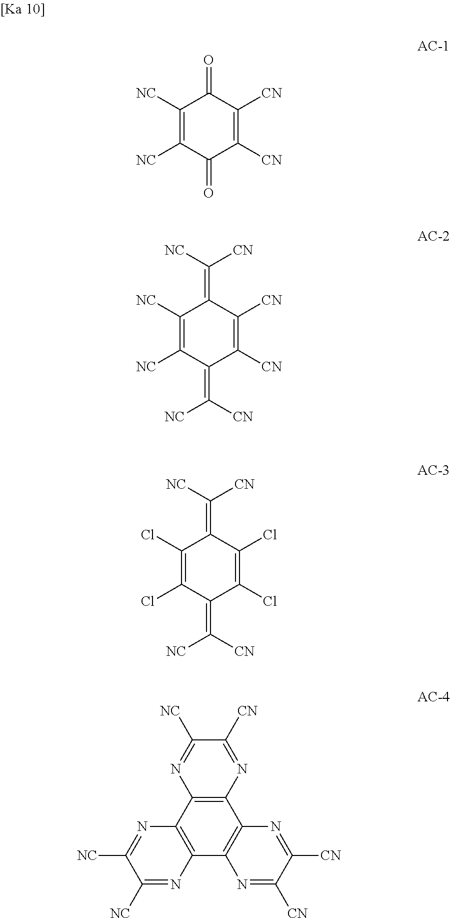 [SMILES: N#CC1=C(C#N)C(=O)C(C#N)=C(C#N)C1=O ; N#CC(C#N)=c1c(C#N)c(C#N)c(=C(C#N)C#N)c(C#N)c1C#N ; N#CC(C#N)=c1c(Cl)c(Cl)c(=C(C#N)C#N)c(Cl)c1Cl ; N#Cc1nc2c3nc(C#N)c(C#N)nc3c3nc(C#N)c(C#N)nc3c2nc1C#N]

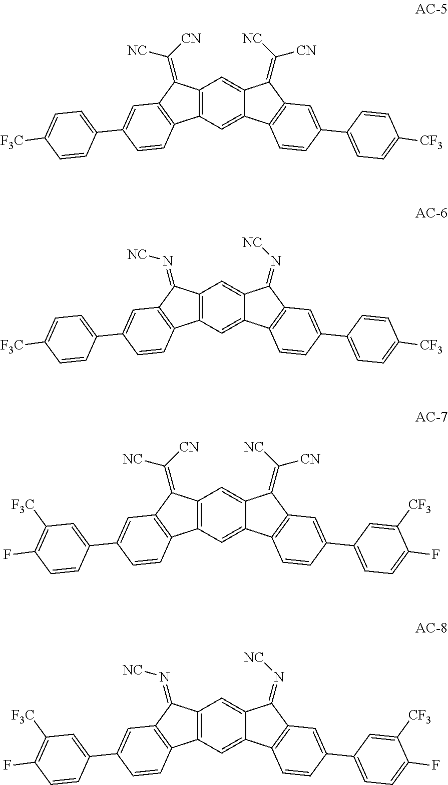 [SMILES: N#CC(C#N)=C1c2cc(-c3ccc(C(F)(F)F)cc3)ccc2-c2cc3c(cc21)C(=C(C#N)C#N)c1cc(-c2ccc(C(F)(F)F)cc2)ccc1-3 ; N#C/N=c1/c2cc(-c3ccc(C(F)(F)F)cc3)ccc2c2cc3c(cc12)/c(=N/C#N)c1cc(-c2ccc(C(F)(F)F)cc2)ccc13 ; N#CC(C#N)=C1c2cc(-c3ccc(F)c(C(F)(F)F)c3)ccc2-c2cc3c(cc21)C(=C(C#N)C#N)c1cc(-c2ccc(F)c(C(F)(F)F)c2)ccc1-3 ; N#C/N=c1/c2cc(-c3ccc(F)c(C(F)(F)F)c3)ccc2c2cc3c(cc12)/c(=N/C#N)c1cc(-c2ccc(F)c(C(F)(F)F)c2)ccc13]

Preferably, the acceptor compound is the radialene derivative represented by the following general formula (3).

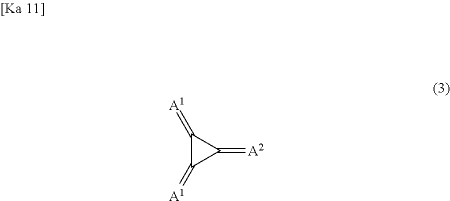

In the general formula (3), Aland A² are each independently cyanomethylidene group modified by replacing hydrogen with an aryl group or a heteroaryl group. In other words, Aland A² are a substituent of cyanomethylidene (═CHCN) group whose hydrogen atom is replaced with an aryl group or a heteroaryl group.

The aryl group and the heteroaryl group are 4-cyano-2,3,5,6-tetrafluorophenyl, 2,3,5,6-tetrafluoropyridin-4-yl, 4-trifluoromethyl-2,3,5,6-tetrafluorophenyl, 2,4-bis(trifluoromethyl)-3,5,6-trifluorophenyl, 2,5-bis(trifluoromethyl)-3,4,6-trifluorophenyl, 2,4,6-tris(trifluoromethyl)-1,3-diazin-5-yl, 3,4-dicyano-2,5,6-trifluorophenyl, 2-cyano-3,5,6-trifluoropyridin-4-yl, 2-trifluoromethyl-3,5,6-trifluoropyridin-4-yl, 2,5,6-trifluoro-1,3-diazin-4-yl, pentafluorophenyl or 3-trifluoromethyl-4-cyano-2,5,6-trifluorophenyl.

At least one of the aryl and the heteroaryl is 2,3,5,6-tetrafluoropyridin-4-yl, 2,4-bis(trifluoromethyl)-3,5,6-trifluorophenyl, 2,5-bis(trifluoromethyl)-3,4,6-trifluorophenyl, 2,4,6-tris(trifluoromethyl)-1,3-diazin-5-yl, 3,4-dicyano-2,5,6-trifluorophenyl, 2-cyano-3,5,6-trifluoropyridin-4-yl, 2-trifluoromethyl-3,5,6-trifluoropyridin-4-yl, 2,5,6-trifluoro-1,3-diazin-4-yl or 3-trifluoromethyl-4-cyano-2,5,6-trifluorophenyl.

A¹ and A² cannot be 2,3,5,6-tetrafluoropyridin-4-yl at the same time.

More preferably, the radialene derivative represented by the general formula (3) are compounds of the following structural formulae.

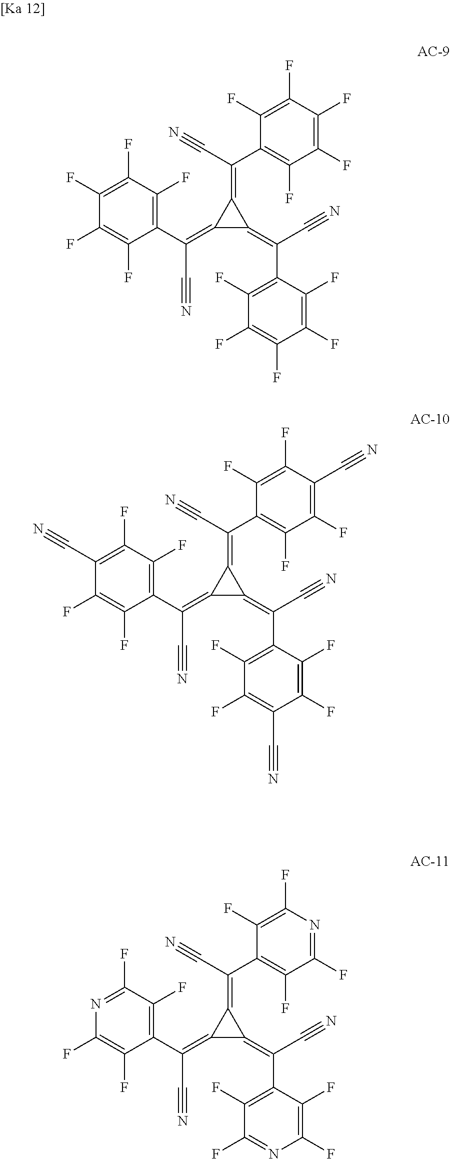

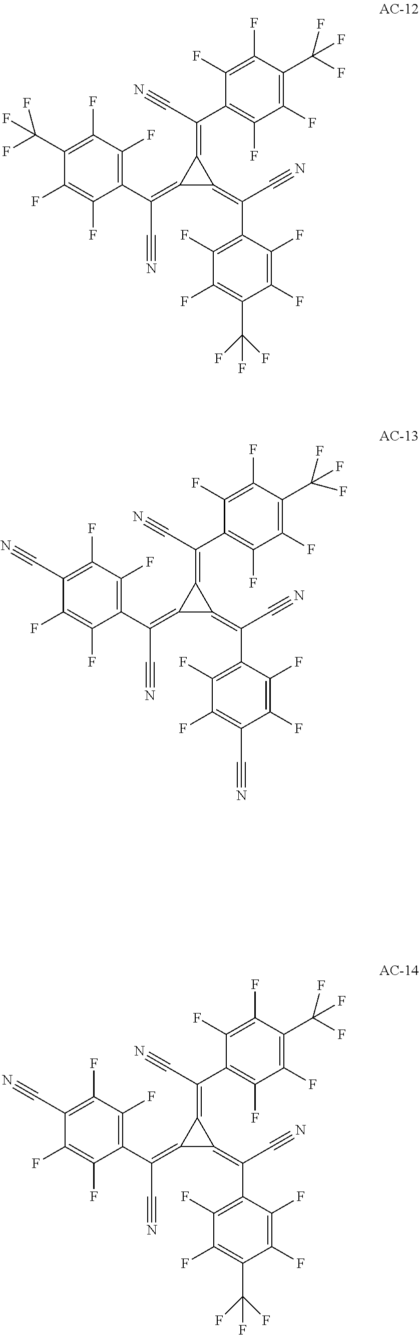

(iv) An electron barrier layer 4 containing the monoamine derivative represented by the following general formula (2) lies between the hole transport layer 3 and the light-emitting layer 5.

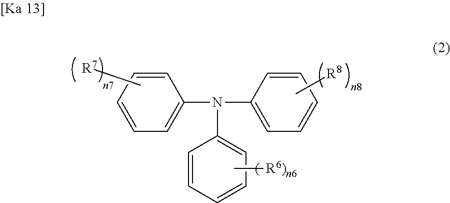

In the general formula (2), R⁶ to R⁸ are each independently hydrogen, deuterium, fluorine, a silyl group, an alkyl group having 1 to 6 carbon atoms, an aryl group having 6 to 30 core carbon atoms or a heteroaryl group having 5 to 30 atoms; n6 to n8 are integers of 1 to 5 and when n6 to n8 is 2 or more, R⁶ to R⁸ may each be the same or different; and adjacent substituents may connect each other to form a saturated or an unsaturated ring.

Specific examples of the silyl group, the alkyl group having 1 to 6 carbon atoms, the aryl group having 6 to 30 core carbon atoms, and the heteroaryl group having 5 to 30 core atoms are the same as those described in the general formula (1).

Preferably, the monoamine derivative represented by the general formula (2) are compounds of the following structural formulae.

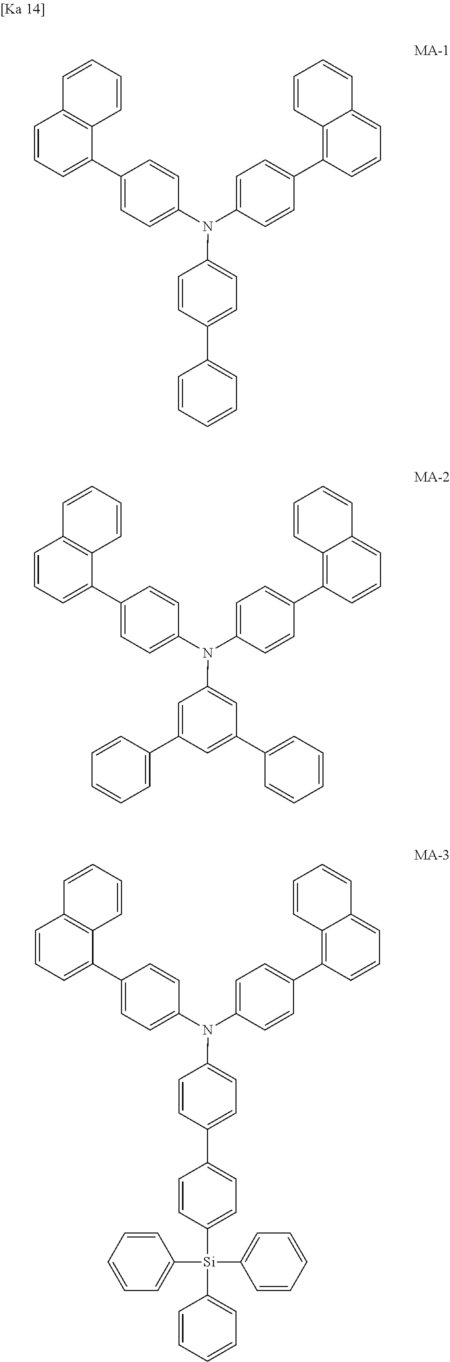

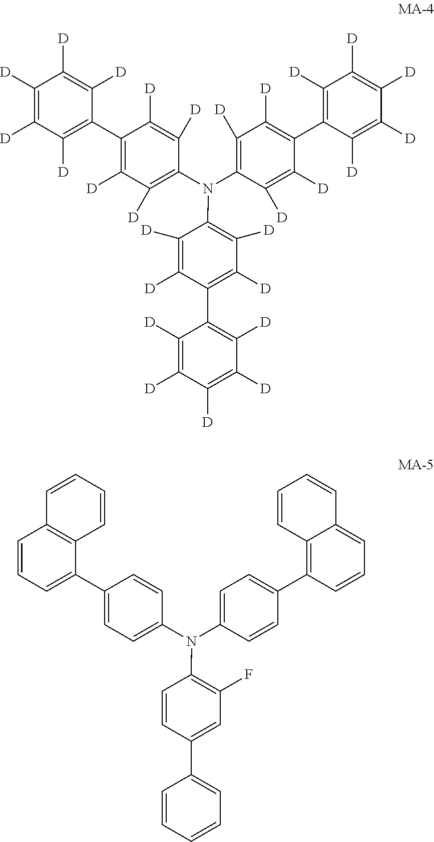

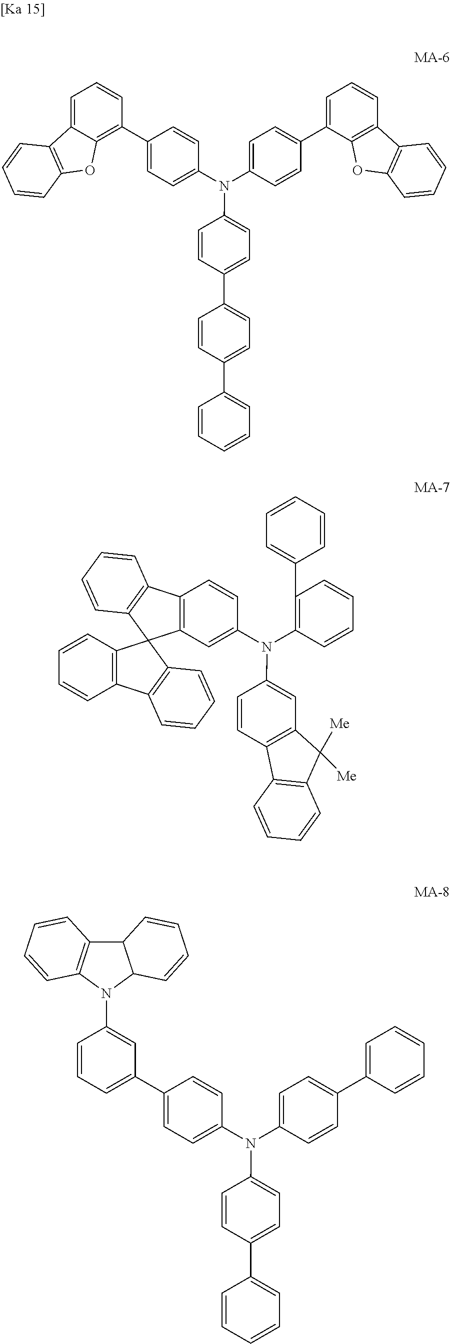

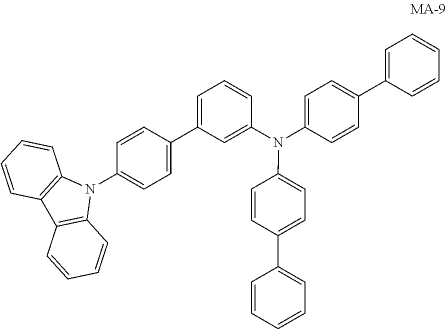

The electron barrier layer 4 has a thickness of 3 to 30 nm and 5 to 20 nm preferably. The thickness in the above range successfully prevents not only pinholes but also uneven thickness from occurring during the film formation.

The electron barrier layer 4 should be thinner than the hole transport layer 3 so as to conduct the electric current at lower voltage. Such a structure enables the organic light-emitting diode to improve efficiency without increasing voltage.

A typical structure of the organic light-emitting diode is explained referring to FIG. 1 as an example.

Transparent and smooth materials having a total light transmittance of at least 70% or more are in use for a substrate (not shown). To be specific, the substrate includes flexible transparent substrates, such as glass substrates having a thickness of some dozens to several hundred of microns and special transparent plastics.

Thin films formed on the substrate, such as the anode 1, the hole injection layer 2, the hole transport layer 3, the electron barrier layer 4, the light-emitting layer 5, the hole barrier layer 6, the electron transport layer 7, the electron injection layer 8 and the cathode 9 are formed by a vacuum deposition method or a coating method. In the case of using the vacuum deposition method, the vapor deposition material is usually heated under a reduced pressure of 10-3 Pa or less. Though the film thickness of each layer is different depending on the type of layers or materials used, the anode 1 and the cathode 9 usually have thicknesses of approximately 100 nm, the hole transport layer a thickness of 40 to 400 nm, the electron barrier layer a thickness of 3 to 30 nm, and the other organic layers such as the light-emitting layer 5 have thicknesses of approximately less than 50 nm each.

Materials used for the anode 1 have high work function and a total light transmittance of 80% or more. To be specific, transparent conductive ceramics such as indium tin oxide (ITO) and zinc oxide (ZnO), transparent conductive polymers such as polythiophene-polystyrene sulfonate (PEDOT-PSS) and polyaniline, and other transparent conductive materials are used to make luminescence from the anode 1 pass through.

In order to transport holes from the anode 1 to the light-emitting layer efficiently, the hole injection layer 2 and the hole transport layer 3 are placed between the anode and the light-emitting layer 5.

The hole injection layer 2, which is also called a polymer buffer layer, is effective in lowering the driving voltage of the organic light-emitting diode. The hole injection layer 2 is made up of the acceptor compound used in the present invention.

Besides the acceptor compound, as far as the effects of the present invention are not impaired, poly(arylene ether ketone)-containing triphenylamine (KLHIP:PPBI), 1,4,5,8,9,11-hexaazatriphenylenehexacarbonitrile (HATCN) and poly(3,4-ethylenedioxythiophene)/poly(4-styrenesulfonic acid) (PEDOT-PSS) can be used together.

The triamine derivative represented by the general formula (1) is used as the hole transport layer 3. The triamine derivative can be used together with the acceptor compound. As far as the effects of the present invention are not impaired, for example, poly(9,9-dioctylfluorene-alt-N-(4-butylphenyl)diphenylamine) (TFB), 4,4′-cyclohexylidenebis[N,N-bis(4-methylphenyl)benzenamine] (TAPC), N,N′-diphenyl-N,N′-di(m-tolyl)benzidine (TPD), N,N′-di(1-naphthyl)-N,N′-diphenylbenzidine (NPD), 4DBFHPB (hexaphenylbenzene derivative), 4,4′,4″-tri-9-carbazolyltriphenylamine (TCTA), 4,4′,4″-tris[phenyl(m-tolyl)amino]triphenylamine, and so on can be used together.

It is preferable that a luminescence material should compose the light-emitting layer 5 together with a host, just like the other light-emitting layers used for the organic light-emitting diode. The luminescence materials include fluorescent dopants made of aromatic hydrocarbon compounds such as a pyrene compound of the following structural formula and anthracene compounds.

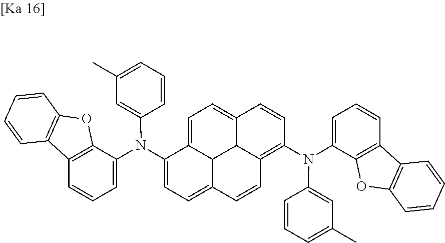 [SMILES: Cc1cccc(N(C2=CC=C3C=CC4=C(N(c5cccc(C)c5)c5cccc6c5oc5ccccc56)C=CC5=CC=C2C3C54)c2cccc3c2oc2ccccc23)c1]

Metal complexes such as tin complexes and copper complexes, and thermally activated delayed fluorescent (TADF) materials such as carbazole compounds, indolocarbazole compounds, cyanobenzene compounds may be also used. Known materials can be widely used for the host, as long as they minimize the charge injection barrier at the hole transport layer 3 and the electron transport layer 7, confine the charge to the light-emitting layer 5, and suppress to quench the light-emitting exciton. An example of the host includes anthracene derivatives of the following structural formulae.

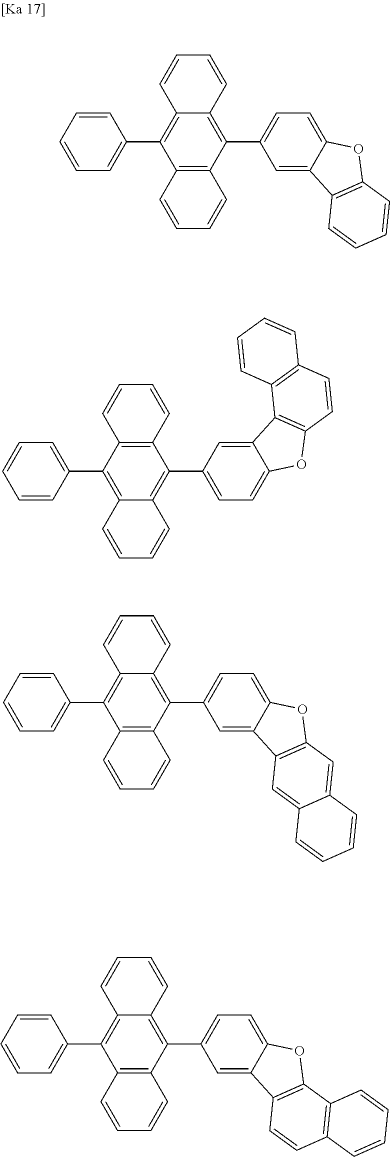 [SMILES: c1ccc(-c2c3ccccc3c(-c3ccc4oc5ccccc5c4c3)c3ccccc23)cc1 ; c1ccc(-c2c3ccccc3c(-c3ccc4oc5ccc6ccccc6c5c4c3)c3ccccc23)cc1 ; c1ccc(-c2c3ccccc3c(-c3ccc4oc5cc6ccccc6cc5c4c3)c3ccccc23)cc1 ; c1ccc(-c2c3ccccc3c(-c3ccc4oc5c6ccccc6ccc5c4c3)c3ccccc23)cc1]

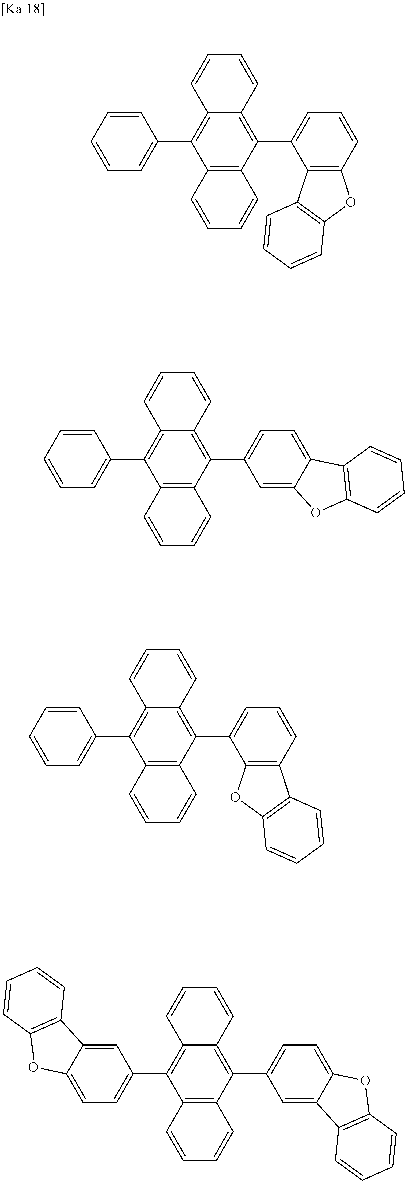 [SMILES: c1ccc(-c2c3ccccc3c(-c3cccc4oc5ccccc5c34)c3ccccc23)cc1 ; c1ccc(-c2c3ccccc3c(-c3ccc4c(c3)oc3ccccc34)c3ccccc23)cc1 ; c1ccc(-c2c3ccccc3c(-c3cccc4c3oc3ccccc34)c3ccccc23)cc1 ; c1ccc2c(c1)oc1ccc(-c3c4ccccc4c(-c4ccc5oc6ccccc6c5c4)c4ccccc34)cc12]

The host is preferably added in an amount of 50 to 99.9 wt %, more preferably 80 to 95 wt % of the total amount of materials for the light-emitting layer 5.

The electron barrier layer 4 is made of the monoamine derivative represented by the general formula (2). The electron barrier layer 4 is placed between the light-emitting layer 5 and the hole transport layer 3 and confines electrons in the light-emitting layer, so that the probability of recombining charges in the light-emitting layer is enhanced, which works out for improving luminous efficiency.

The hole barrier layer 6 and the electron transport layer 7 are placed between the light-emitting layer 5 and the cathode 9 in order to transport electrons efficiently from the cathode 9 to the light-emitting layer 5. The thicknesses of the hole barrier layer 6 and the electron transport layer 7 are 3 to 50 nm which can be modified according to the design for the purpose.

The hole barrier layer 6 is made of compounds of the following structural formula, bathocuproine (BCP), and dibenzothiophene-triphenyltriazine (DBT-TRZ). The hole barrier layer 6 works for enhancing luminous efficiency, because holes are confined in the light-emitting layer 5 and the probability of recombining charges in the light-emitting layer 5 is enhanced.

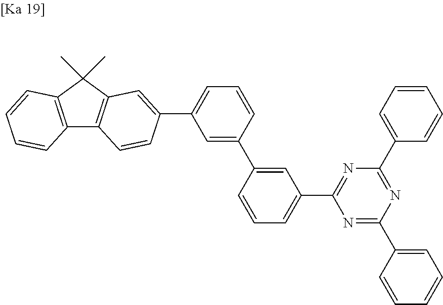 [SMILES: CC1(C)c2ccccc2-c2ccc(-c3cccc(-c4cccc(-c5nc(-c6ccccc6)nc(-c6ccccc6)n5)c4)c3)cc21]

The electron transport layer 7 is made up of a compound having the structural formula described below, 1,4-bis(1,10-phenanthroline-2-yl)benzene (DPB), 8-hydroxyquinolinolatolithium (Liq), 4,6-bis(3,5-di(pyridin-3-yl)phenyl)-2-methylpyrimidine (B3PymPm), 4,6-bis(3,5-di(pyridin-4-yl)phenyl)-2-phenylpyrimidine (B4PyPPm), 2-(4-biphenylyl)-5-(p-t-butylphenyl)-1,3,4-oxadiazole (tBu-PBD), 1,3-bis[5-(4-t-butylphenyl)-2-[1,3,4]oxadiazolyl]benzene (OXD-7), 3-(biphenyl-4-yl)-5-(4-t-butylphenyl)-4-phenyl-4H-1,2,4-triazole (TAZ), bathocuproine (BCP), 1,3,5-tris(1-phenyl-1H-benzimidazol-2-yl)benzene (TPBi) or 3-(4-biphenyl)-4-phenyl-5-(4-t-butylphenyl)-1,2,4-triazole (TAZ).

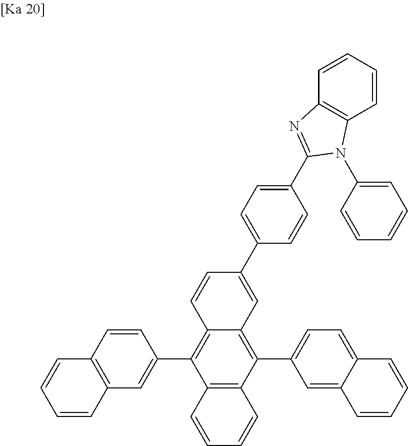 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

The electron injection layer 8 is made up of lithium fluoride (LiF) and lithium 2-hydroxy-2,2′-bipyridyl-6-yl phenolate (Libpp), for example.

Chemically stable materials having low work function of 4 eV or less are used for the cathode 9. To be specific, Al, Mg—Ag alloy, and Al-alkali metal alloy (e.g., Al—Li), and Al—Ca alloy are used for the cathode material. These cathode materials are filmed by resistance heating evaporation, electron beam evaporation, sputtering, or ion plating, for example.

### EXAMPLES

Hereinafter, the present invention will be described in detail referring to the examples, but the present invention is not restricted to the examples.

### Examples 1 to 6

A glass substrate of 26 mm×28 mm×0.7 mm (manufactured by Opto Science Inc.,), on which ITO was sputtered to a thickness of 180 nm and then polished to 150 nm, was used as a transparent support substrate.

The transparent support substrate was fixed to a substrate holder of a commercially available vapor deposition apparatus (manufactured by Showa Shinku Co., Ltd.). The vapor deposition apparatus was equipped with a vapor deposition boat made of molybdenum containing an acceptor compound (AC-4, AC-5 or AC-10) for forming the hole injection layer 2, a vapor deposition boat made of molybdenum containing a triamine derivative (TA-1 or TA-8) for forming the hole transport layer 3, a vapor deposition boat made of molybdenum containing a monoamine derivative (MA-6, MA-7 or MA-8) for forming the electron barrier layer 4, each of vapor deposition boats made of molybdenum containing a host material (BH1: a compound of the following structural formula) and a blue light-emitting material (BD1: a compound of the following structural formula) for forming the light-emitting layer 5, a vapor deposition boat made of molybdenum containing HBL (a compound of the following structural formula) as a hole barrier material, vapor deposition boats made of molybdenum containing ETM (a compound of the following structural formula) and 8-hydroxyquinolinolato-lithium (Liq) each as electron transport materials, a vapor deposition boat made of molybdenum containing lithium fluoride (LiF) as an electron injection material, and a vapor deposition boat made of tungsten containing aluminum for forming the cathode 9.

Table 1 shows the combinations of the acceptor compounds for forming the hole injection layer (HIL), the triamine derivatives for forming the hole transport layer 3, and the monoamine derivatives for forming the electron barrier layer 4 as in Examples 1 to 6.

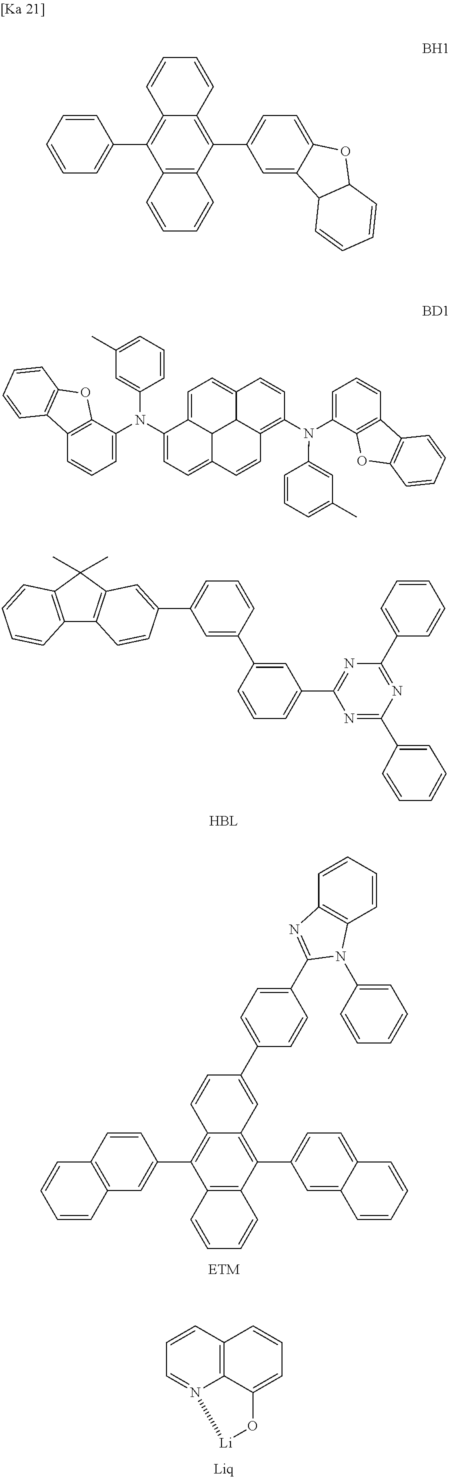

Each layer was successively formed on the ITO film of the transparent support substrate as described above. The inside pressure of a vacuum chamber was reduced to 5×10⁻⁴ Pa, and first of all, the vapor deposition boat containing the acceptor compound (AC-4, AC-5 or AC-10) was heated, so that the acceptor compound was vaporized and formed into the hole injection layer 2 with a thickness of 5 nm. Next, the vapor deposition boat containing the triamine derivative (TA-1 or TA-8) was heated, so that the triamine derivative was vaporized and formed into the hole transport layer 3 with a thickness of 145 nm. The vapor deposition boat containing the monoamine derivative (MA-6, MA-7 or MA-8) was heated, so that the monoamine derivative was vaporized and formed into the electron barrier layer 4 with a thickness of 5 nm.

The vapor deposition boat containing BH1 and the other one containing BD1 were heated at the same time, and the light-emitting layer 5 was deposited to a thickness of 25 nm. The vapor deposition rates were controlled so as to give a weight ratio of BH1 and BD1 approximately 95:5.

The vapor deposition boat containing HBL was heated, so that HBL was vaporized and formed into the hole barrier layer 6 with a thickness of 10 nm. And the vapor deposition boat containing ETM and the one containing Liq were heated, so that ETM and Liq were vaporized and formed into the electron transport layer 7 with a thickness of 25 nm. The vapor deposition rates were controlled so as to give a weight ratio of ETM and Liq approximately 1:1.

The vapor deposion rate of each layer was 0.01 to 2 nm/s. The vapor deposition boat containing LiF was heated, and the electron injection layer 8 was formed with a thickness of 1 nm at a vapor deposition rate of 0.01 to 0.1 nm/s. Thus the vapor deposition boat containing aluminum was heated, and the cathode 9 was formed with a thickness of 100 nm at a vapor deposition rate of 0.01 to 2 nm/s. Thus the organic light-emitting diode was prepared.

When the direct current was applied to the elemental device with an ITO electrode as the anode 1 and a LiF/aluminum electrode as the cathode 9, blue light emission was observed.

The current density and the current efficiency of the elemental device were measured when a voltage of 5V was applied to this elemental device. The results of Examples 1 to 6 are shown in Table 1.

### Comparative Examples 1 to 3

Organic light-emitting diodes of Comparative Examples 1 and 2 were prepared in a manner similar to Examples 3 and 4, except that as a hole transport material, the compound of the following structural formula (DA-1 or CZ-1) was used instead of the triamine derivative (TA-1 or TA-8).

An organic light-emitting diode of Comparative Example 3 was prepared in a manner similar to Example 1, except that as an electron barrier material, the compound of the following structural formula (DA-1) was used instead of the triamine derivative (MA-6).

Similarly to Examples 1 to 6, the current density and the current efficiency were measured under the voltage of 5V. The results are shown in Table 1.

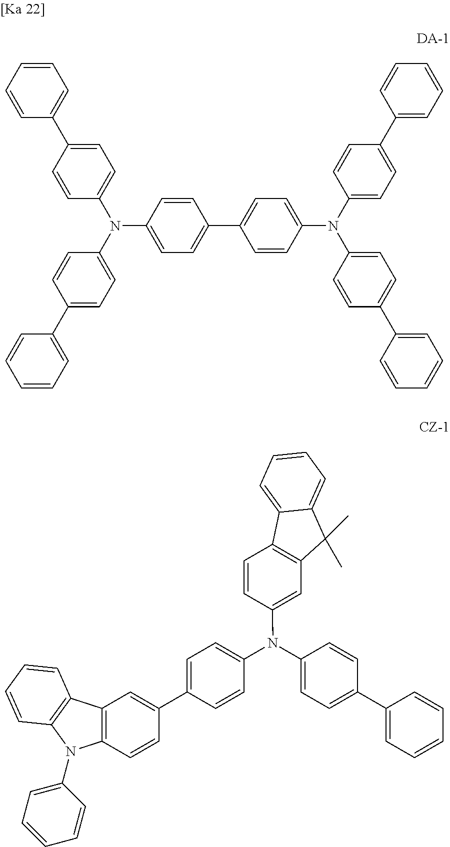 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

TABLE 1

| | | Current | Current |
|---|---|---|---|
| | HIL/HTL/EBL*⁾ | Density@5 V | Efficiency@5 V |
| Ex. 1 | AC-4/TA-1/MA-6 | 48 mA/cm² | 8.5 cd/A |
| Ex. 2 | AC-5/TA-1/MA-6 | 46 mA/cm² | 8.6 cd/A |
| Ex. 3 | AC-10/TA-1/MA-6 | 45 mA/cm² | 8.5 cd/A |
| Ex. 4 | AC-10/TA-8/MA-6 | 47 mA/cm² | 8.7 cd/A |
| Ex. 5 | AC-10/TA-1/MA-7 | 45 mA/cm² | 8.6 cd/A |
| Ex. 6 | AC-10/TA-1/MA-8 | 47 mA/cm² | 8.5 cd/A |
| Comp. | AC-10/DA-1/MA-6 | 38 mA/cm² | 7.8 cd/A |
| Ex. 1 | | | |
| Comp. | AC-10/CZ-1/MA-6 | 37 mA/cm² | 7.7 cd/A |
| Ex. 2 | | | |
| Comp. | AC-4/TA-1/DA-1 | 4 7 mA/cm² | 6.8 cd/A |
| Ex. 3 | | | |

*⁾HIL represents a hole injection layer, HTL a hole transport layer, and EBL an electron barrier layer.

### Examples 7 to 12

A glass substrate of 26 mm×28 mm×0.7 mm (manufactured by Opto Science Inc.,), on which ITO was sputtered to a thickness of 180 nm and then polished to 150 nm, was used as a transparent support substrate.

This transparent support substrate was fixed to a substrate holder of a commercially available vapor deposition apparatus (manufactured by Showa Shinku Co., Ltd.). The vapor deposition apparatus was equipped with a vapor deposition boat made of molybdenum containing an acceptor compound (AC-4, AC-5 or AC-10) for forming the hole injection layer 2, a vapor deposition boat made of molybdenum containing a triamine derivative (TA-1 or TA-8) for forming the hole injection layer 2 and the hole transport layer 3, a vapor deposition boat made of molybdenum containing a monoamine derivative (MA-6, MA-7 or MA-8) for forming the electron barrier layer 4, each of vapor deposition boats made of molybdenum containing BH1 (a host material) and BD1 (a blue light-emitting material) for forming the light-emitting layer 5, a vapor deposition boat made of molybdenum containing HBL as a hole barrier material, vapor deposition boats made of molybdenum containing ETM and 8-hydroxyquinolinolato-lithium (Liq) each as electron transport materials, a vapor deposition boat made of molybdenum containing lithium fluoride (LiF) as an electron injection material, and a vapor deposition boat made of tungsten containing aluminum for forming the cathode 9.

Table 2 shows the combinations of the acceptor compounds for forming the hole injection layer 2, the triamine derivatives for forming the hole transport layer 3 and the monoamine derivatives for forming the electron barrier layer 4 as in Examples 7 to 12.

Each layer was formed on the ITO film of the transparent support substrate in the order described below. The inside pressure of a vacuum chamber was reduced to 5×10⁻⁴ Pa, and first of all, the vapor deposition boat containing the acceptor compound (AC-4, AC-5 or AC-10) and the vapor deposition boat containing the triamine derivative (TA-1 or TA-8) were heated, so that the acceptor compound and the triamine derivative were vaporized and formed into a hole injection/transport layer with a thickness of 40 nm. The vapor deposition rates were controlled so as to give a weight ratio of the acceptor compound and the triamine derivative approximately 3:97. Next, the vapor deposition boat containing the triamine derivative was heated, so that the triamine derivative was vaporized and formed into the hole transport layer 3 with a thickness of 110 nm. The vapor deposition boat containing the monoamine derivative (MA-6, MA-7 or MA-8) was heated, so that the monoamine derivative was vaporized and formed into the electron barrier layer 4 with a thickness of 5 nm.

The vapor deposition boat containing BH1 and the other one containing BD1 were heated at the same time, and the light-emitting layer 5 was deposited to a thickness of 25 nm. The vapor deposition rates were controlled so as to give a weight ratio of BH1 and BD1 at approximately 95:5.

The vapor deposition boat containing HBL was heated, so that HBL was vaporized and formed into the hole barrier layer 6 with a thickness of 10 nm. And the vapor deposition boat containing ETM and the one containing Liq were heated, so that ETM and Liq were vaporized and formed into the electron transport layer 7 with a thickness of 25 nm. The vapor deposition rates were controlled so as to give a weight ratio of ETM and Liq approximately 1:1.

The vapor deposion rate of each layer was 0.01 to 2 nm/s.

The vapor deposition boat containing LiF was heated, and the electron injection layer 8 was formed into a thickness of 1 nm at a vapor deposition rate of 0.01 to 0.1 nm/s. The vapor deposition boat containing aluminum was heated, and the cathode 9 was formed into a thickness of 100 nm at a vapor deposition rate of 0.01 to 2 nm/s. Thus the organic light-emitting diode was prepared.

When the direct current was applied to the elemental device with an ITO electrode as the anode 1 and a LiF/aluminum electrode as the cathode 9, blue light emission was observed.

The current density and the current efficiency of the elemental device were measured when a voltage of 5V was applied to the elemental device. The results of Examples 7 to 12 are shown in Table 1.

### Comparative Examples 4 to 6

Organic light-emitting diodes of Comparative Examples 4 and 5 were prepared in a manner similar to Examples 9 and 10, except that as a hole transport material, the compound of the following structural formula (DA-1 or CZ-1) was used instead of the triamine derivative (TA-1 or TA-8).

An organic light-emitting diode of Comparative Example 6 was prepared in a manner similar to Example 7, except that as an electron barrier material, the compound of the following structural formula (DA-1) was used instead of the triamine derivative (MA-6).

Similarly to Examples 7 to 12, the current density and the current efficiency were measured under the voltage of 5V. The results are shown in Table 2.

TABLE 2

| | | Current | Current |
|---|---|---|---|
| | HIL/HTL/EBL*⁾ | Density@5 V | Efficiency@5 V |
| Ex. 7 | AC-4/TA-1/MA-6 | 51 mA/cm² | 8.2 cd/A |
| Ex. 8 | AC-5/TA-1/MA-6 | 47 mA/cm² | 8.2 cd/A |
| Ex. 9 | AC-10/TA-1/MA-6 | 48 mA/cm² | 8.4 cd/A |
| Ex. 10 | AC-10/TA-8/MA-6 | 49 mA/cm² | 8.5 cd/A |
| Ex. 11 | AC-10/TA-1/MA-7 | 46 mA/cm² | 8.6 cd/A |
| Ex. 12 | AC-10/TA-1/MA-8 | 46 mA/cm² | 8.4 cd/A |
| Comp. | AC-10/DA-1/MA-6 | 38 mA/cm² | 7.7 cd/A |
| Ex. 4 | | | |
| Comp. | AC-10/CZ-1/MA-6 | 37 mA/cm² | 7.7 cd/A |
| Ex. 5 | | | |
| Comp. | AC-4/TA-1/DA-1 | 48 mA/cm² | 6.9 cd/A |
| Ex. 6 | | | |

*⁾HIL represents a hole injection layer, HTL a hole transport layer, and EBL an electron barrier layer.

The compound of the present invention is recognized to produce blue light emission at lower voltage than that of the well-known art.

### REFERENCE SIGNS LIST

1 anode
2 hole injection layer
3 hole transport layer
4 electron barrier layer
5 light-emitting layer
6 hole barrier layer
7 electron transport layer
8 electron injection layer
9 cathode

1. An organic light-emitting diode in which an organic thin film including at least a light-emitting layer is sandwiched between an anode and a cathode, and satisfies the following (i) to (iv):
(i) the organic thin film includes a hole transport layer containing a triamine derivative represented by the following general formula (1);
(ii) the hole transport layer has a thickness of 40 to 400 nm;
(iii) a part or the whole of the hole transport layer contains 0.1 to 20 wt % of an acceptor compound, and/or the hole transport layer includes a hole injection layer made of the acceptor compound between the anode and the hole transport layer; and
(iv) an electron barrier layer containing a monoamine derivative represented by the following general formula (2) is included between the hole transport layer and the light-emitting layer: 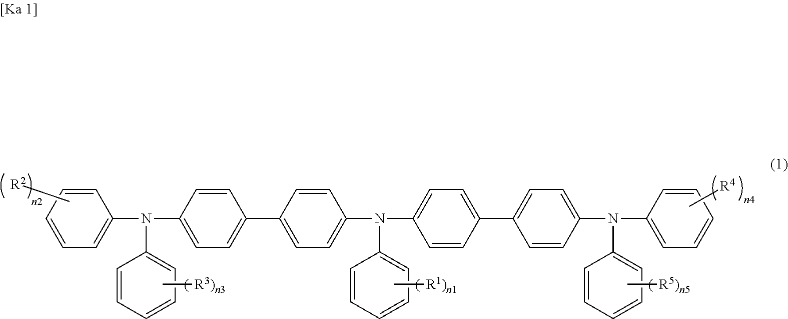
in the general formula (1), R¹ to R⁵ are each independently hydrogen, deuterium, fluorine, a silyl group, an alkyl group having 1 to 6 carbon atoms, an aryl group having 6 to 30 core carbon atoms or a heteroaryl group having 5 to 30 core atoms; n1 to n5 are integers of 1 to 5 and when n1 to n5 are 2 or more, R¹ to R⁵ may each be the same or different; among R¹ to R⁵, two adjacent substituents may connect each other to form a saturated or unsaturated ring; and 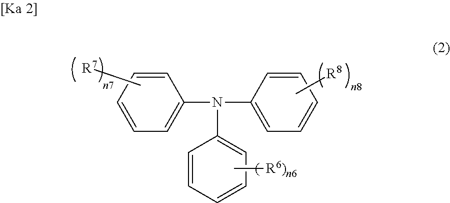
in the general formula (2), R⁶ to R⁸ are each independently hydrogen, deuterium, fluorine, a silyl group, an alkyl group having 1 to 6 carbon atoms, an aryl group having 6 to 30 core carbon atoms or a heteroaryl group having 5 to 30 core atoms; n6 to n8 are integers of 1 to 5 and when n6 to n8 is 2 or more, R⁶ to R⁸ may each be the same or different; and two adjacent substituents may connect each other to form a saturated or unsaturated ring.

2. The organic light-emitting diode according to claim 1, wherein the acceptor compound has a reversible oxidation-reduction potential in a range of +0.10 to +0.50 V by cyclic voltammetry in acetonitrile solution on the basis of the ferrocenium/ferrocene redox couple (Fc+/Fc).

3. The organic light-emitting diode according to claim 1, wherein the acceptor compound is a radialene derivative represented by the following general formula (3): 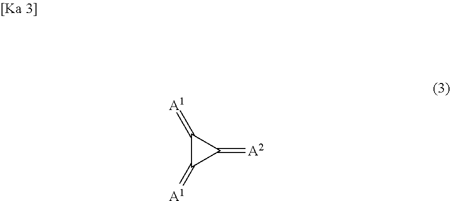
in the general formula (3), Aland A² are each independently cyanomethylidene group modified by replacing hydrogen with an aryl group or a heteroaryl group; the aryl group and the heteroaryl group are 4-cyano-2,3,5,6-tetrafluorophenyl, 2,3,5,6-tetrafluoropyridin-4-yl, 4-trifluoromethyl-2,3,5,6-tetrafluorophenyl, 2,4-bis(trifluoromethyl)-3,5,6-trifluorophenyl, 2,5-bis(trifluoromethyl)-3,4,6-trifluorophenyl, 2,4,6-tris(trifluoromethyl)-1,3-diazin-5-yl, 3,4-dicyano-2,5,6-trifluorophenyl, 2-cyano-3,5,6-trifluoropyridin-4-yl, 2-trifluoromethyl-3,5,6-trifluoropyridin-4-yl, 2,5,6-trifluoro-1,3-diazin-4-yl, pentafluorophenyl or 3-trifluoromethyl-4-cyano-2,5,6-trifluorophenyl, and at least one of the aryl and the heteroaryl is 2,3,5,6-tetrafluoropyridin-4-yl, 2,4-bis(trifluoromethyl)-3,5,6-trifluorophenyl, 2,5-bis(trifluoromethyl)-3,4,6-trifluorophenyl, 2,4,6-tris(trifluoromethyl)-1,3-diazin-5-yl, 3,4-dicyano-2,5,6-trifluorophenyl, 2-cyano-3,5,6-trifluoropyridin-4-yl, 2-trifluoromethyl-3,5,6-trifluoropyridin-4-yl, 2,5,6-trifluoro-1,3-diazin-4-yl or 3-trifluoromethyl-4-cyano-2,5,6-trifluorophenyl, and A¹ and A² cannot be 2,3,5,6-tetrafluoropyridin-4-yl at the same time.
